(19) United States
(12) Patent Application Publication
(10) Pub. No.: US 2008/0079175 A1
(43) Pub. Date: Apr. 3, 2008

(54) LAYER FOR CHIP CONTACT ELEMENT

(76) Inventors: Michael Bauer, Nittendorf (DE); Christian Stuempfl, Schwandorf (DE); Ludwig Heitzer, Regensburg (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/537,873

(22) Filed: Oct. 2, 2006

(51) Int. Cl. H01L 23/48; H01L 21/00

(52) U.S. Cl. 257/778; 438/108; 257/E23.021

(57) ABSTRACT

A chip (1) or a semiconductor wafer having a contact element (2) for electrical contact-connection is described. In this case, the contact element (2) is covered with an organic layer (3).

The invention relates to semiconductor wafers and chips having electrical contact elements. In particular, the invention relates to protecting such contact elements against oxidation or other environmental influences.

Chips and even wafers, too, have electrical contact elements such as contact pads or solder balls, for example, via which the chip is brought into contact electrically with its surroundings. In this case, oxidation or other alterations of such contact elements caused by environmental influences make the contact-connecting step more difficult and may bring about a reduction in the electrical and/or mechanical contact quality.

Such difficulties can be avoided if the contact-connecting or bonding process is carried out under a protective or forming gas atmosphere. No oxide is formed at the surface of the contact element in this case. However, the chip contact-connection using a protective or forming gas requires a complicated process implementation and furthermore has reliability problems.

A further conventional possibility for avoiding oxidation processes on contact elements consists in plating said contact elements with a metal layer, in particular made of nickel, which has a lower tendency toward oxidation and serves as an oxygen barrier. Intermetallic alloys form in the contact region during this procedure, as a result of which undesirable effects may occur.

A first aspect provides a chip having a contact element for the electrical contact-connection of the chip. The contact element is covered with an organic layer. This impedes or prevents e.g. formation of oxide at the contact element.

A second aspect provides an arrangement comprising a chip with wire bonding contact-connection. The chip comprises a contact area for a wire connection, the contact area having been covered with an organic layer before the fitting of the wire to the contact area.

A third aspect provides a semiconductor wafer having contact elements for the electrical contact-connection of electrically operable structures. The contact elements are covered with an organic layer.

Furthermore, methods for producing a semiconductor wafer, for producing a chip, for the wire contact-connection of a chip and for the contact-connection of a chip by means of solder ball elements are provided in which contact elements with an organic layer are used.

Embodiments are described below in an exemplary manner with reference to figures, in which:

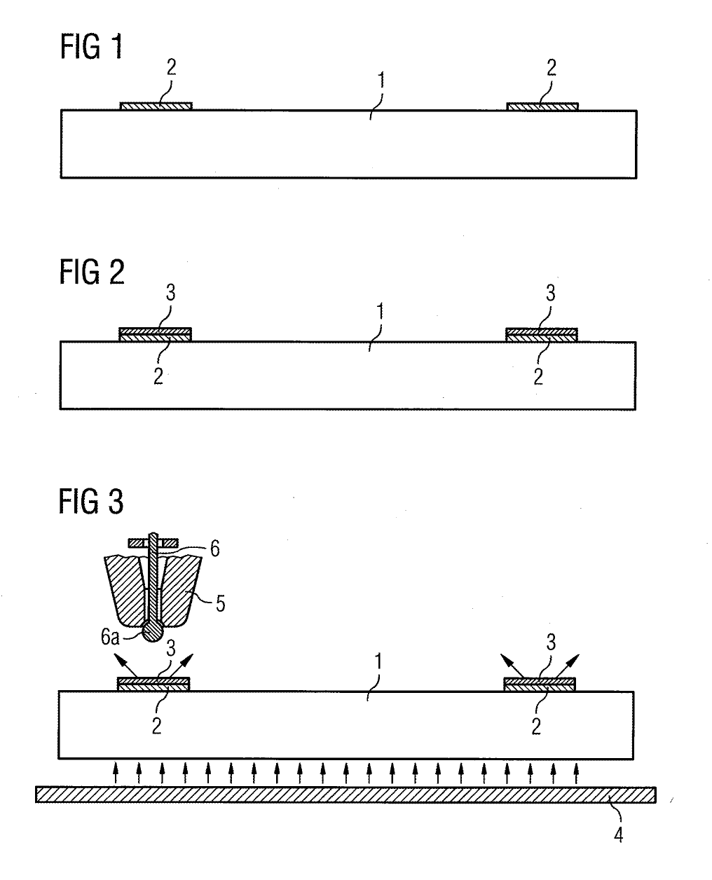

FIG. 1 shows a chip with a chip contact;

FIG. 2 shows a chip with a chip contact covered by an organic surface protection layer;

FIG. 3 shows the chip illustrated in FIG. 2 adjacent to a heat source;

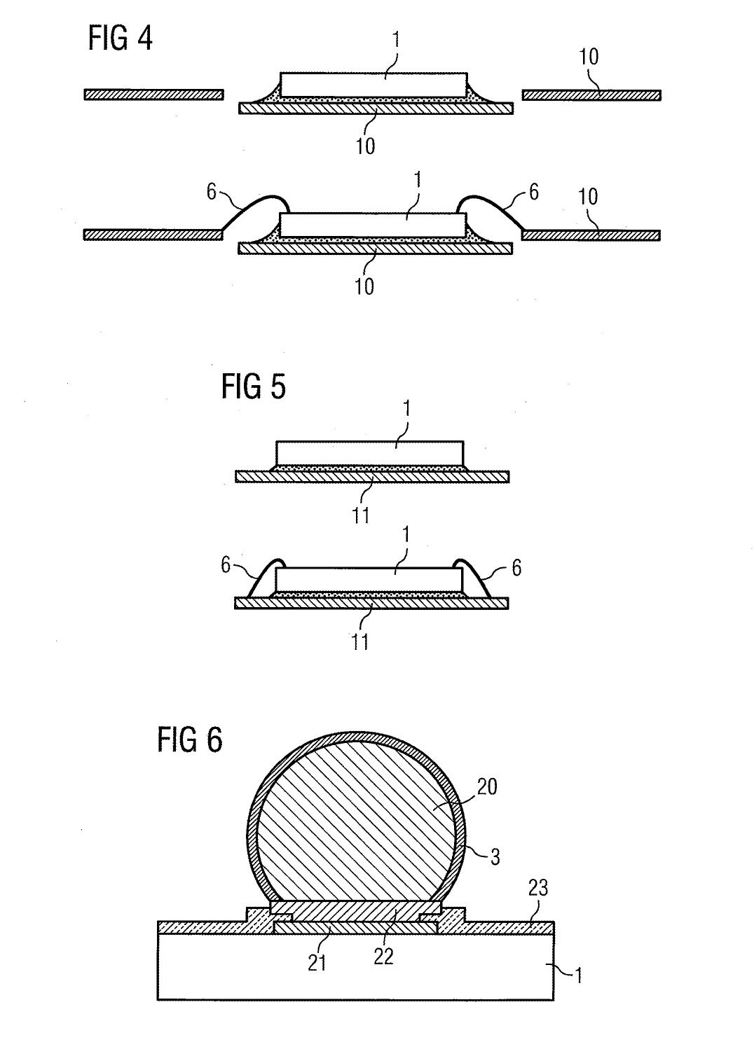

FIG. 4 shows the production of a wire bonding connection between a chip and a leadframe;

FIG. 5 shows the production of a wire bonding connection between a chip and an interposer;

FIG. 6 shows a contact element in the form of a solder ball fitted to a chip or semiconductor wafer;

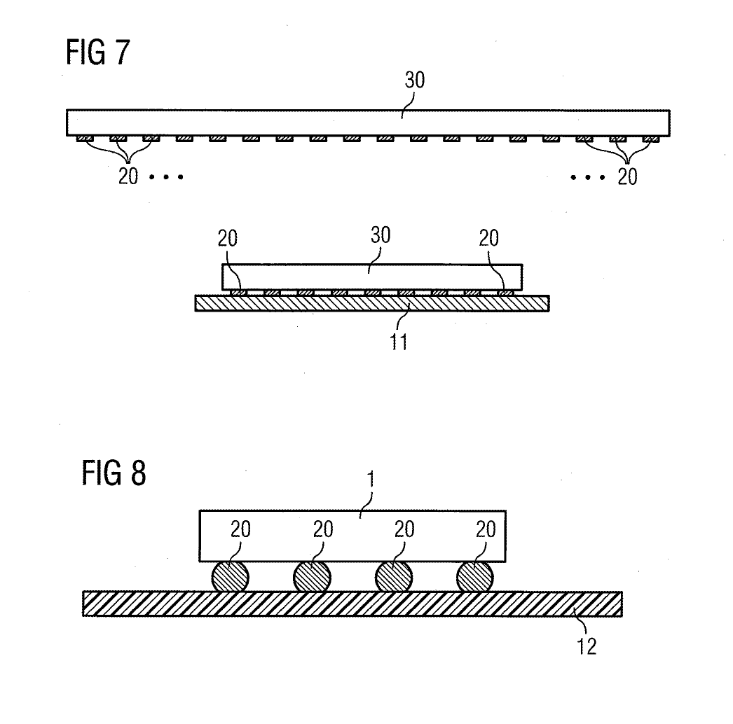

FIG. 7 shows a flip-chip arrangement on an interposer;

FIG. 8 shows a flip-chip arrangement on a printed circuit board;

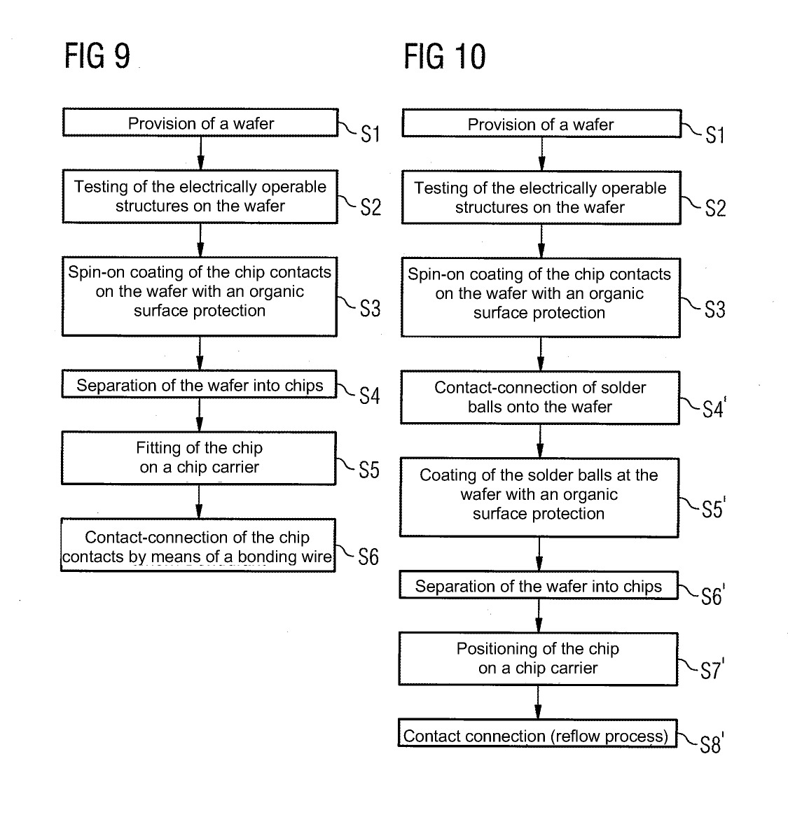

FIG. 9 shows a flowchart for illustrating a method for the wire bonding contact-connection of a chip to a chip carrier; and

FIG. 10 shows a flowchart for illustrating a flip-chip contact-connection of a chip on a chip carrier.

A description is given below of chips, semiconductor wafers and arrangements of chips on chip carriers and also methods for producing such structures in which chip- or wafer-side contact elements have been or are covered with an organic layer. In this case, the electrically operable structures formed in the semiconductor wafer and also the chips may be of a wide variety of types and contain in particular electrical, electromechanical and/or electro-optical components, e.g. integrated circuits, sensors, actuators, microelectromechanical components, laser diodes, etc. The contact elements may be e.g. metallic connecting areas which are formed on the wafer in the process of producing the latter. The contact elements are preferably a copper-based compound or pure copper. However, they may also be subsequently fitted contact elements, such as, for example, solder balls and the like.

All materials whose surface degrades under environmental action can be covered and thus protected by the organic layer. In particular, protection against oxidation can be achieved by means of the organic layer, that is to say that an oxide layer that impairs the contact-connection process is prevented from forming due to the action of air at the surface of the contact element.

An organic surface protection layer can be removed or perforated for example by the action of heat or mechanical action before or during the contact-connecting process. Since both a wire bonding contact-connection and a reflow process typically involves applying heat for the formation of the contacts, the material for the organic layer can be chosen such that the organic layer evaporates from the contact element, preferably in a manner essentially free of residues, at the contact-connection temperatures that usually occur (e.g. temperatures>200° C. during wire bonding). Since the contact element is not uncovered until directly before the contact-connection process in this case, disturbing formation of oxide before the contact-connection instant is no longer possible.

The material for the organic surface protection layer should be thermally stable after application at ambient temperatures and form a durable, adherent, in particular solid protection layer. A suitable material is, for example, Imidazole or derivatives thereof and an aromatic heterocyclic nitrogen compound or derivatives thereof.

Chip carriers may be any type of carriers which are suitable for mounting a chip, e.g. metallic carriers, ceramic carriers or carriers comprising an organic material. By way of example, a leadframe, an interposer, a printed circuit board (PCB) or else a second chip may be provided as the chip carrier.

FIG. 1 shows a chip 1 having chip contacts 2 fitted to its outer side. The chip contacts 2 are electrically connected to wiring planes in the chip 1 in a manner that is not specifically illustrated. They are freely accessible from the outer side, with the result that the chip 1 can be contact-connected via the chip contacts 2. The chip contacts 2 are metallic and may be copper or aluminum contacts, for example.

The chip contacts 2 are unprotected against oxidation processes. Therefore, an undefined oxide layer forms on said contacts 2. A high tendency towards oxidation is present particularly in the case of copper contacts.

In order to avoid the formation of an oxide layer, an organic surface protection layer 3 (OSP: Organic Surface Protection), which affords protection against oxidation or other environmental influences, is applied to the chip contacts 2. Said layer forms with the chip contact 2 a compound that is stable but, if appropriate, volatile with heat being supplied.

FIG. 3 shows a wire bonding process in a simplified illustration. During wire bonding, a thin metal wire 6, preferably made of copper, is fixed to the chip contact 2. Directly before or during the wire bonding process, heat is transferred to the chip 1 and thus to the chip contacts 2 by means of a hot plate 4. The organic surface protection layer 3 is essentially completely removed again as a result of the input of heat. The bonding, that is to say the fixing of the bonding wire 6 to the non-oxidized metallic chip contact (wire bonding contact pad) 2, is subsequently effected.

In the case of a copper-copper bonding, neither an intermetallic mixed phase nor an oxide phase occurs, therefore, in the contact region.

The wire bonding contact-connection is carried out in an automatic wire contact-connecting machine (so-called “wire bonder”). As will be explained in more detail later, the chip 1 has already been fixedly connected to a chip carrier (e.g. interposer or leadframe) at this point in time. The hot plate 4 in the wire bonder is situated below the chip carrier (not illustrated in FIG. 3), that is to say that the chip carrier with the chip 1 fitted thereon bears on the hot plate 4. The bonding wire 6 required for the contact-connection is fed via a thin cannula 5. The capillary 5 simultaneously serves as a pressing-on tool. A wire ball 6a formed at the free end of the bonding wire 6 by melting is pressed onto the chip contact 2 by the capillary 5 being lowered and is thereby fixed to said chip contact. Ultrasonic energy is coupled in during the pressing-on process. The temperature of the hot plate 4, the coupling in of ultrasonic energy and also the pressing-on pressure employed are parameters which influence the quality of the bonding connection. Wire bonding temperatures of above 200° C. are usually present.

The material of the surface protection layer 3 can be chosen such that the latter evaporates from the chip contact 2 in a manner free of residues only at the wire bonding temperatures that usually occur (that is to say e.g. at 200° C. or higher). By way of example, a material based on Imidazole, derivatives thereof or heterocyclic nitrogen compounds is suitable for this. However, it is also possible that at the temperatures mentioned surface protection layer 3 is not evaporated, rather it is broken up and “plated-through” during the contact-connection process.

FIGS. 4 and 5 illustrate different possibilities for contact-connecting a chip 1 to a chip carrier. A leadframe 10 is used as the chip carrier in FIG. 4. A so-called interposer 11, that is to say a substrate, is used as the chip carrier in FIG. 5. The upper illustrations in FIGS. 4 and 5 in each case show the fitting of the chip 1 on the respective chip carrier 10, 11 (“die attach”).

Besides the electrical contact-connection, the task of the chip carrier 10, 11 consists in providing a mechanically and thermally defined support for the chip 1. The lower illustrations in FIGS. 4 and 5 show the already described formation of a wire connection (wire bonding) between the chip 1 and the respective chip carrier 10, 11.

FIG. 6 shows a further possibility for the contact-connection of a chip 1. The contact-connection is effected by means of a solder ball 20 fitted on a metallic contact area 21, e.g. made of aluminum or copper, of the chip 1. The contact area 21 corresponds to the chip contact 2 in FIGS. 1 to 3 and may have the properties of said chip contact. Further electrically conductive intermediate layers 22, for example an adhesion layer and/or a wetting layer, etc., may be situated between the metallic contact area 21 and the solder ball 20. A passivation layer 23 may surround the contact area 21.

The organic surface protection layer 3 already described in association with the wire bonding contact-connection (FIGS. 1 to 3) is situated on the surface of the solder ball 20 here in accordance with a first embodiment. The solder ball 20 is thus protected against oxidation or other environmental influences.

FIGS. 7 and 8 illustrate different possibilities for fitting a chip 1 by flip-chip contact-connection on a chip carrier. In the case of the flip-chip arrangement, the active surface of the chip 1 always faces the chip carrier.

In accordance with the upper illustration in FIG. 7, firstly solder balls 20 are fitted to metallic contact areas 21 of a semiconductor wafer 30 (“wafer bumping”). This may be effected e.g. by means of a galvanic process. The wafer 30 with the solder balls 20 already fitted is then separated into chips 1 (“dicing”). Each chip 1 is then positioned onto a chip carrier, the electrical contact-connection being effected by means of the solder balls 20. For this purpose, the solder balls 20 are melted by the action of heat and in the process form an electrically conductive contact with opposite contact areas (not illustrated) on the chip carrier (“reflow soldering”).

As illustrated in FIG. 7, each chip 1 may be applied on an individual chip carrier 11 in the form of an interposer or substrate. The interposer 11 is then potted with the chip 1 and fitted to an electrical printed circuit board (not illustrated) by means of suitable electrical contact-connections. Another possibility consists in contact-connecting the chip 1 directly in a flip-chip arrangement onto a printed circuit board 12, which in this case serves as a chip carrier for one or a plurality of chips 1. In both cases, the organic surface protection layer 3 on the solder balls 20 is destroyed or evaporated during the reflow process.

A further embodiment consists in fitting the organic surface protection layer 3 prior to fitting the solder ball 20 on the metallic contact area 21. The organic surface protection layer 3 is then situated, with solder ball 20 not yet fitted, at the place of the intermediate layer 22 discernible in FIG. 6. Since the organic surface protection layer 3 is removed before or during the fitting of the solder ball 20, it is no longer present in FIG. 6.

The two embodiments can be combined, that is to say that it is possible firstly to fit an organic surface protection layer 3 on the metallic contact area 21 and, after forming the solder ball 20 at the contact area 21, the solder ball 20 can be coated with the organic surface protection layer 3 in the manner already described.

FIG. 9 illustrates in an exemplary manner method steps for the wire bonding contact-connection of a chip 1 in accordance with FIGS. 1 to 5. A semiconductor wafer is provided in a first step S1. The electrically operable structures of the wafer are tested in step S2. This is followed by the coating of the chip contacts 2 on the wafer with the organic surface protection layer 3 in step S3. A spin-on coating method may be carried out for this purpose. During this method, the organic surface protection layer 3 wets only the metallic chip contacts 2 and not the rest of the surface of the wafer, that is to say that there is typically no need for the applied organic surface protection layer 3 to be patterned.

The organic surface protection layer 3 may also be fitted on the metallic chip contacts 2 in some other way. By way of example, a dipping method may be used instead of the spin-on coating method. The dipping method may be carried out both for the wafer and—at a later point in time—for the individual chips 1. The chip contacts 2 at the wafer are then protected particularly with regard to a relatively long time duration (storage, transport) until further processing.

In a later step S4, the wafer is separated into individual chips 1. Afterward, in steps S5 and S6, the chips 1 are fitted to the chip carriers 10, 11 and contact-connected by means of bonding wires 6 in the manner already described.

FIG. 10 illustrates in an exemplary manner the production process in the case of the flip-chip contact-connection illustrated in FIGS. 6 to 8. In steps S1 and S2, the wafer 30 is provided and the electrical structures on the wafer 30 are tested, as in FIG. 9. The testing may also be effected at a later point in time, e.g. after step S4′ yet to be described.

If an organic surface protection layer 3 is intended to be fitted over the metallic contact areas 21, this is effected in step S3. A spin-on method may be used for this purpose, as in the method according to FIG. 9.

In a step S4′, the solder balls 20 are contact-connected to the wafer 30, the organic surface protection layer 3 on the metallic contact areas 21 being eliminated beforehand or during the contact-connecting.

The solder balls 20 can be coated with the organic surface protection layer in the subsequent step S5′. The solder balls are then protected particularly with regard to a relatively long time duration (storage, transport) until further processing.

Later, the wafer 30 is separated into individual chips 1 (step S6′). The chips 1 are then positioned on a chip carrier 11, 12 and, in step S8′, contact-connected by means of a reflow process in the manner already described.

It holds true for the embodiments that the methods and measures described are compatible with existing methods and production apparatuses used in chip making. As a result, a cost saving and method simplification are achieved in comparison with the conventional procedure (use of a protective or forming gas, use of a metal coating as oxidation barrier). Particularly when using chip contacts 2 or contact areas 21 made of pure copper and copper wires 6 for the wire bonding, the advantage is afforded that no intermetallic phase is formed and the reliability of the connection is thereby increased. A reduction process is not necessary in this case since no oxide layer forms on the copper. The cost-effectiveness of the method (copper wires are very attractively priced anyway) is additionally increased as a result.

1.-39. (canceled)

40. A chip, comprising:
a contact element for an electrical contact-connection of the chip; and
an organic layer at least partially covering the contact element.

41. The chip according to claim 40, wherein the contact element has a wire connection contact area adapted for a wire connection.

42. The chip according to claim 40, wherein the contact element has a flip-chip contact-connection contact area adapted for a flip-chip contact-connection.

43. The chip according to claim 40, wherein the contact element comprises at least one of copper and a copper-based substance.

44. The chip according to claim 40, wherein the contact element is a solder ball element.

45. The chip according to claim 40, wherein the organic layer comprising a substance which evaporates during a contact-connection process.

46. The chip according to claim 40, wherein the organic layer contains at least one of imidazole and derivatives thereof.

47. The chip according to claim 40, wherein the organic layer contains at least one of a heterocyclic nitrogen compound and derivatives thereof.

48. An arrangement, comprising:
a chip;
a contact area formed on the chip for a wire connection;
an organic layer disposed over at least a portion of the contact area; and
a wire contacting the contact area.

49. The arrangement according to claim 48, wherein the contact area comprises at least one of copper and a copper-based substance.

50. The arrangement according to claim 48, wherein the wire comprises at least one of copper and a copper-based substance.

51. A semiconductor wafer, comprising:
a surface of the wafer;
a plurality of contact elements disposed on the surface of the wafer and configured for the electrical contact-connection of electrically operable structures of the semiconductor wafer; and
an organic layer disposed on at least a portion of each of the plurality of contact elements.

52. The semiconductor wafer according to claim 51, wherein the contact elements each comprise respective contact areas for wire connections.

53. The semiconductor wafer according to claim 51, wherein the contact elements each comprise contact areas for a flip-chip contact-connection.

54. The semiconductor wafer according to claim 51, wherein the contact elements are made of at least one of copper and a copper-based substance.

55. The semiconductor wafer according to claim 51, wherein the contact elements comprise solder ball elements.

56. The semiconductor wafer according to claim 51, wherein the organic layer contains at least one of imidazole and derivatives thereof.

57. The semiconductor wafer according to claim 51, wherein the organic layer containing a heterocyclic nitrogen compound or derivatives thereof.

58. The semiconductor wafer according to claim 51, wherein the organic layer comprises a substance which evaporates during a contact-connection process.

59.-77. (canceled)
